(19) United States
(12) Patent Application Publication
(10) Pub. No.: US 2011/0038109 A1
(43) Pub. Date: Feb. 17, 2011

(54) MULTI-SWIVEL DUAL SCREEN DISPLAY

(75) Inventors: Shao-Yu Hwang, Taipei City (TW); Guan-De Liou, Taipei City (TW)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: HANNSPREE, INC., Taipei County (TW)

(21) Appl. No.: 12/853,815

(22) Filed: Aug. 10, 2010

(30) Foreign Application Priority Data
Aug. 11, 2009 (CN) 200910166505.4

(51) Int. Cl. H05K 7/00

(52) U.S. Cl. 361/679.01

(57) ABSTRACT

A multi-swivel dual screen display, comprises a display body having a screen and a concave slot, wherein the concave slot is disposed on a top of the screen; a protective cover includes a second screen; and a ball joint having a first end and a second end, wherein the first end is pivotally coupled to the protective cover, and the second end connected to the concave slot of the display body thus enable the protective cover to be multi-swivel in all positions. The multi-swivel dual screen allows the user to use the display and at the same time displaying common or vital information on the second screen. When the display is not in use, the protective cover can be swivel in front of the screen protecting the screen from dust and scratches.

### CROSS-REFERENCES TO RELATED APPLICATIONS

This non-provisional application claims priority under 35 U.S.C. §119(a) on Patent Application No(s). 200910166505.4 filed in China. on Aug. 11, 2009, the entire contents of which are hereby incorporated by reference.

### FIELD OF THE INVENTION

The present invention relates to a display, and more particularly to a display having a multi-swivel dual screen.

### BACKGROUND OF THE INVENTION

As technologies advance and improve, the display of information is faster and greater. The user is no longer able to view all the information in a single display screen. When the user launches a number of windows on a conventional display it's a great hassle for the user to switch between different windows to view each window. If displaying all the windows on the same screen, the windows will overlap each other or shrinking all windows to fit in a single screen, thus will be too small and difficult for the user to view the information.

Furthermore, conventional displays don't normally provide a protective cover, thus after a long time of use the screen can be easily damaged or scratched. Furthermore, the display screen consists of electrostatic and can attract dust particles, hence the display screen requires to clean regularly.

### SUMMARY OF THE INVENTION

A multi-swivel dual screen display, comprises a display body having a screen and a concave slot, wherein the concave slot is disposed on the top of the screen; a protective cover includes a second screen; and a ball joint having a first end and a second end, wherein the first end is pivotally coupled to the protective cover, and the second end connected to the concave slot of the display body thus enable the protective cover to be multi-swivel in all positions.

Wherein the ball joint and concave slot is a tight fit joint.

Wherein the screen is a touch panel screen.

Wherein the second screen is a touch panel screen.

Wherein the protective cover comprises a first cover, a second cover and a hinge,

Wherein the hinge is pivotally connects the first cover and the second cover.

Wherein the second cover is pivotally coupled to the ball joint.

Wherein the protective cover has same size as the display body.

Wherein a solar panel is disposed on the protective cover.

Wherein a solar panel is disposed on the first cover.

Wherein the first cover having a light source.

Wherein the second cover includes a third screen.

### BRIEF DESCRIPTION OF THE DRAWINGS

The foregoing aspects, as well as many of the attendant advantages and features of the present invention will become more apparent by reference to the following detailed description, when taken in conjunction with the accompanying drawings, wherein:

FIG. 1 shows the perspective view of a multi-swivel dual screen display according to a preferred embodiment of the present invention;

FIG. 2 shows the side view of the multi-swivel dual screen display according to a preferred embodiment of the present invention;

FIG. 3 shows the perspective view of the multi-swivel dual screen display in the first position;

FIG. 4A shows the section view of the ball joint;

FIG. 4B shows the top view of the multi-swivel dual screen display according to a preferred embodiment of the present invention;

FIG. 5 shows the movements of the multi-swivel dual screen display according to a preferred embodiment of the present invention;

FIG. 6 shows the perspective view of the multi-swivel dual screen display in the second position;

FIG. 7 shows the perspective view of the multi-swivel dual screen display in the third position;

FIG. 8 shows the perspective view of a multi-swivel dual screen display according to another preferred embodiment of the present invention;

FIG. 9 shows the perspective view of a multi-swivel dual screen display according to another preferred embodiment of the present invention in the first position; and

FIG. 10 shows the perspective view of a multi-swivel dual screen display according to another preferred embodiment of the present invention in the second position.

### DETAILED DESCRIPTION OF THE PREFERRED EMBODIMENTS

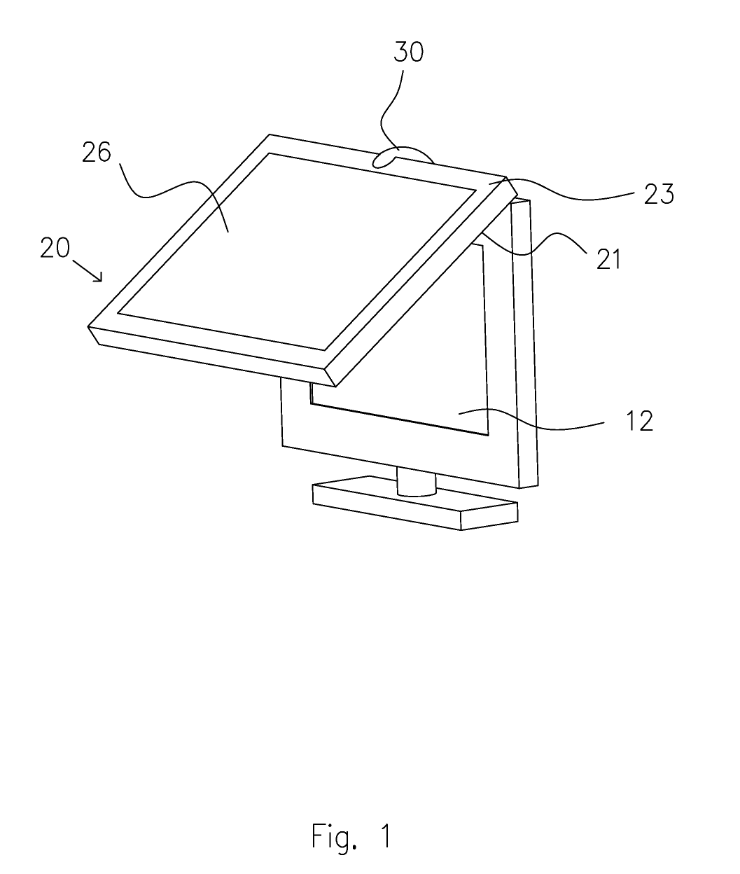

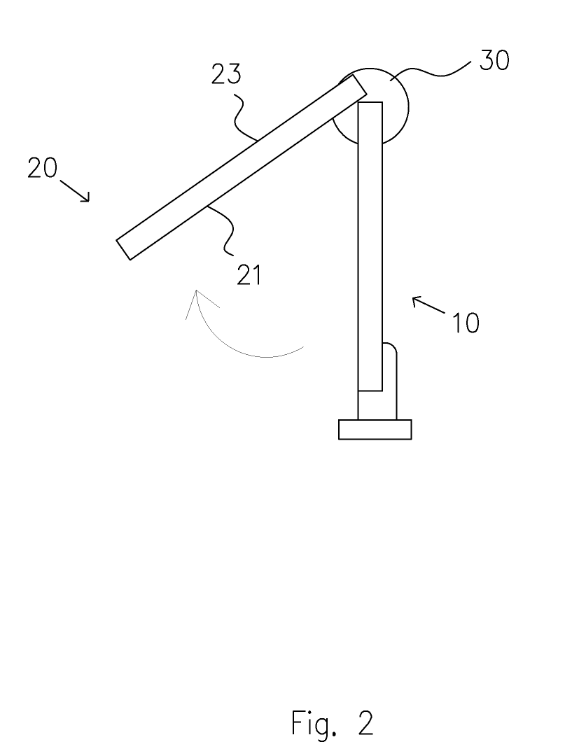

FIG. 1 to FIG. 7 shows the preferred embodiment, a multi-swivel dual screen display comprises a display body 10, a protective cover 20 and a ball joint 30.

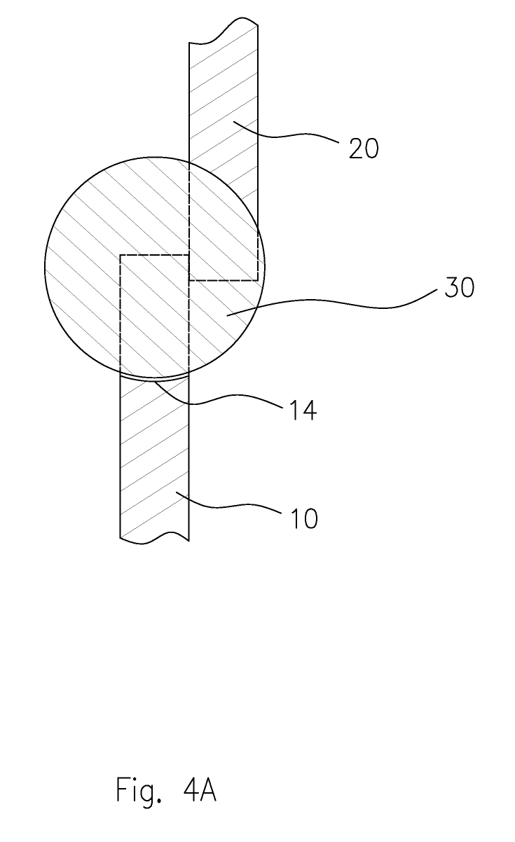

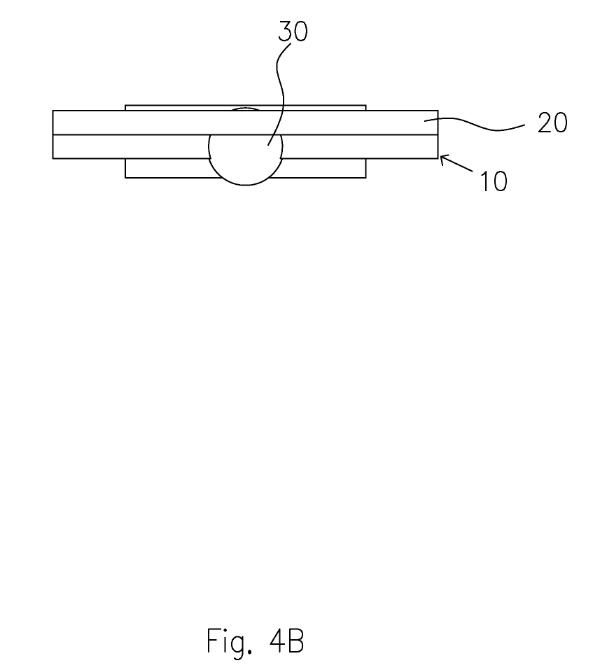

Please referring to FIG. 1 to FIG. 4, in the embodiment, the display body 10 includes a screen 12 and a concave slot 14 disposed on the top of the screen 12. The concave slot 14 is in a shape of a ball and is pivotally coupled to the ball joint 30 providing a multi-swivel motion. Referring to FIG. 4A, the ball joint 30 having a first end and a second end, the first end is pivotally coupled to the protective cover 20, and the second end connected to the concave slot 14 of the display body 10, thus enable the protective cover 20 to be multi-swivel in all positions. The ball joint 30 is assembled tight fit inside the concave slot 14 and provided multi-swivel movement inside the concave slot 14 as shown in FIG. 4B.

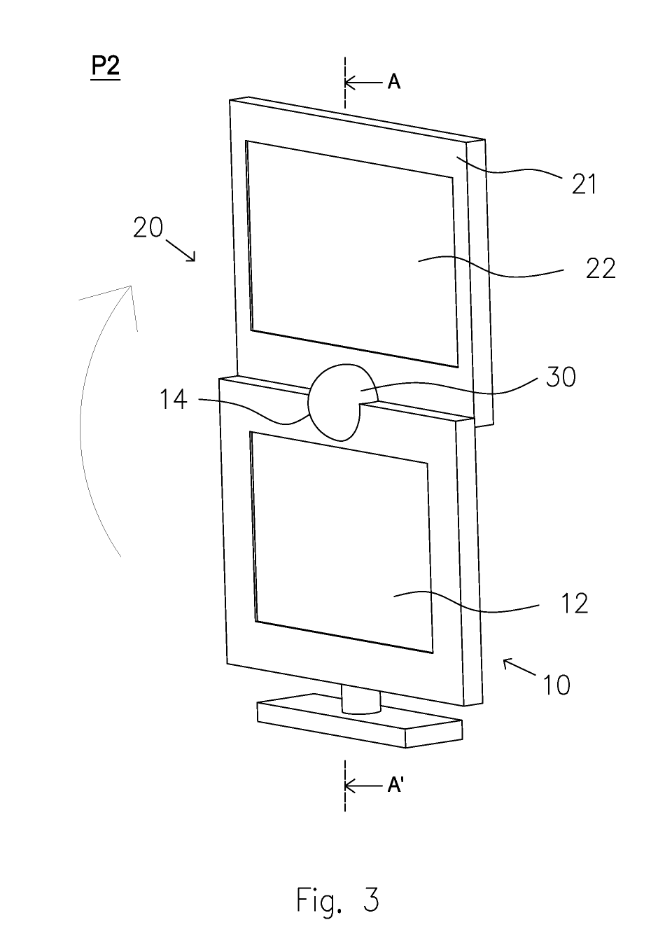

In the embodiment, the protective cover 20 comprises an inner face 21 and an outer face 23. A second screen 22 is disposed on the inner face 21 of the protective cover 20, and a solar panel 26 is disposed on the outer face 23 of the protective cover 20. When the protective cover 20 is swiveled upwards to the second position P2 and the second screen 22 is facing the user as shown in FIG. 3. The second screen 22 provides the user a second display to view extra information without interfere with the main screen 12. Plug-in software such as MSN, Skype, chat room, and etc. can be displayed on the second screen 22, therefore the pop-up messages won't overlap the information displayed on the main screen 12 and affecting the user. In addition, the second screen 22 can be touch panel screen or a digital photo frame displayed pictures and photos.

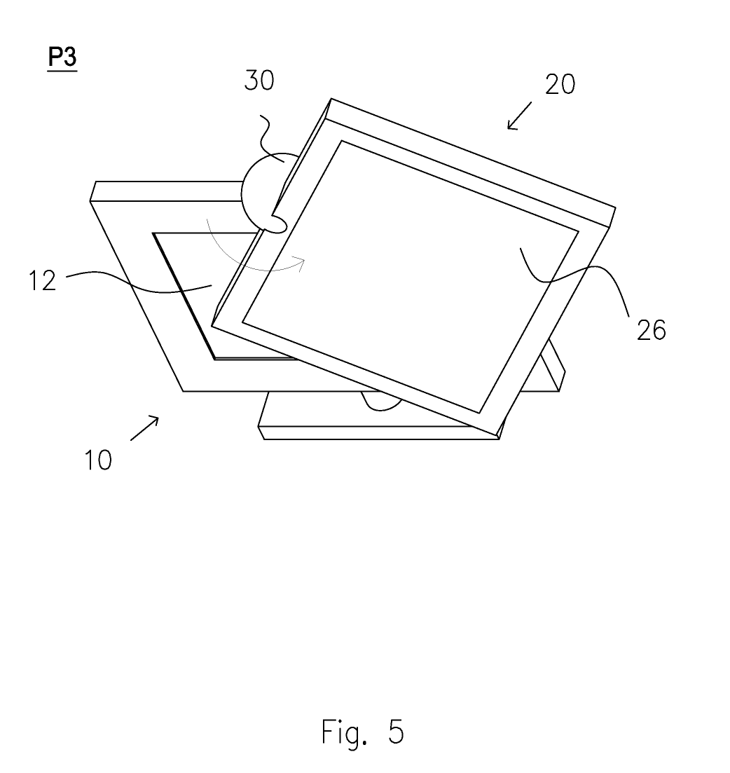

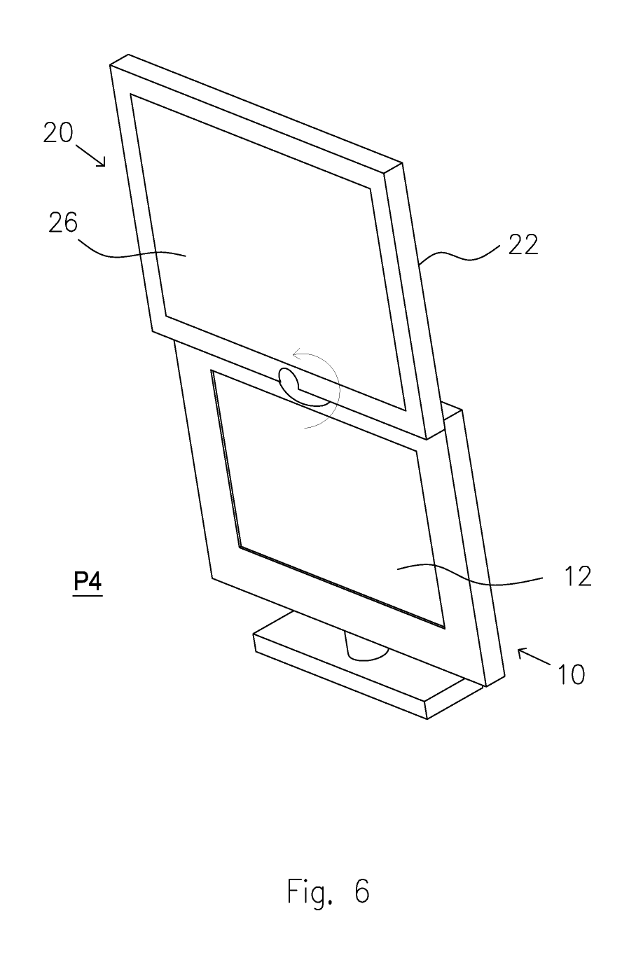

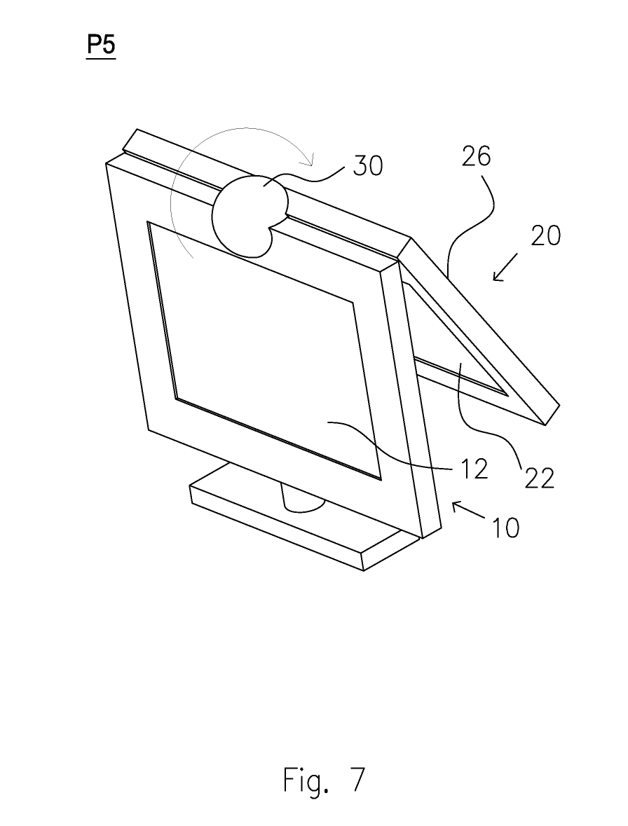

Please referring to FIG. 5 to FIG. 7, the protective cover 20 can swivel in all directions. As shown in FIG. 5, the protective cover 20 swivel sideways into the third position P3 showing a part of screen 12. The protective cover 20 can also swivel from the third position P3 to the fourth position P4 (as shown in FIG. 6), hence, the second screen 22 is facing opposite the screen 12, allows the user to provide images or information to the person sitting opposite. Referring to FIG. 7, the protective cover 22 can swivel from the fourth position P4 to the fifth position P5, rotating the protective cover 20 facing upwards or facing sunlight, hence, the solar panel 26 on the protective cover 20 absorbs the sunlight then converts the solar energy into electricity and supply it to the display.

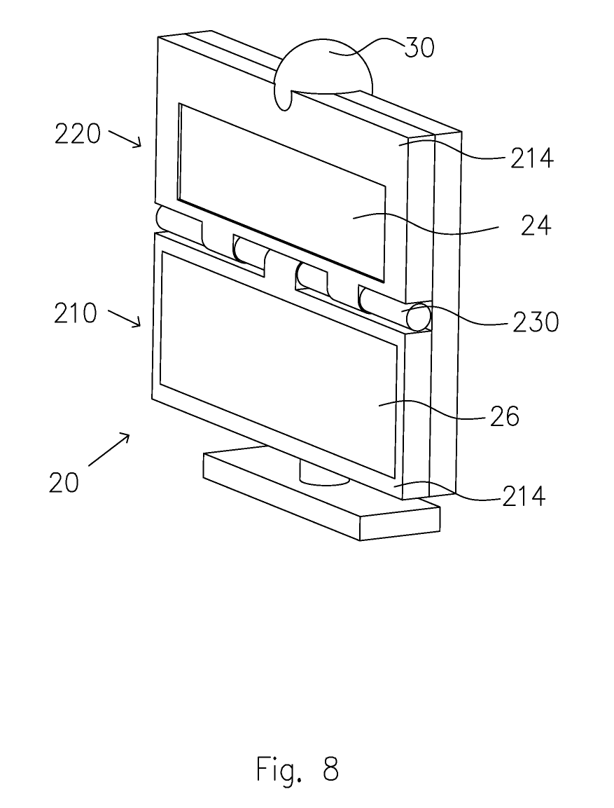

FIG. 8 to FIG. 10 shows the second embodiment, wherein the protective cover 20 comprises a first cover 210, a second cover 220 and a hinge 230, the hinge 230 is pivotally connects the first cover 210 and the second cover 220. The other end of the second cover 220 is pivotally coupled to the ball joint 30 providing a multi-swivel motion. In the embodiment, the fist cover 210 and second cover 220 both having an inner face 212 and an outer face 214.

In the embodiment, the first cover 210 comprises a light source 28 on the inner face 212 and a solar panel 26 on the outer face 214. Furthermore, the second cover 220 comprises a second screen 22 on the inner face 212 and a third screen 24 on the outer face 214. Referring to FIG. 8, when the display is not in use, the protective cover 20 can be swiveled in front of the screen 12 protecting the screen 12 from dust and scratches.

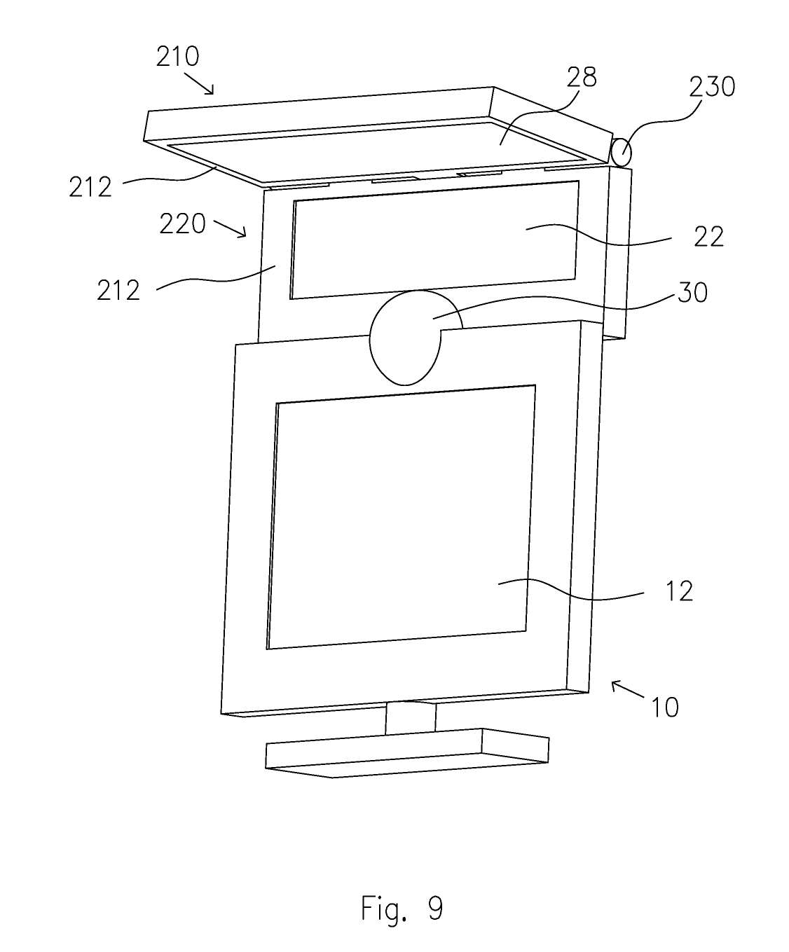

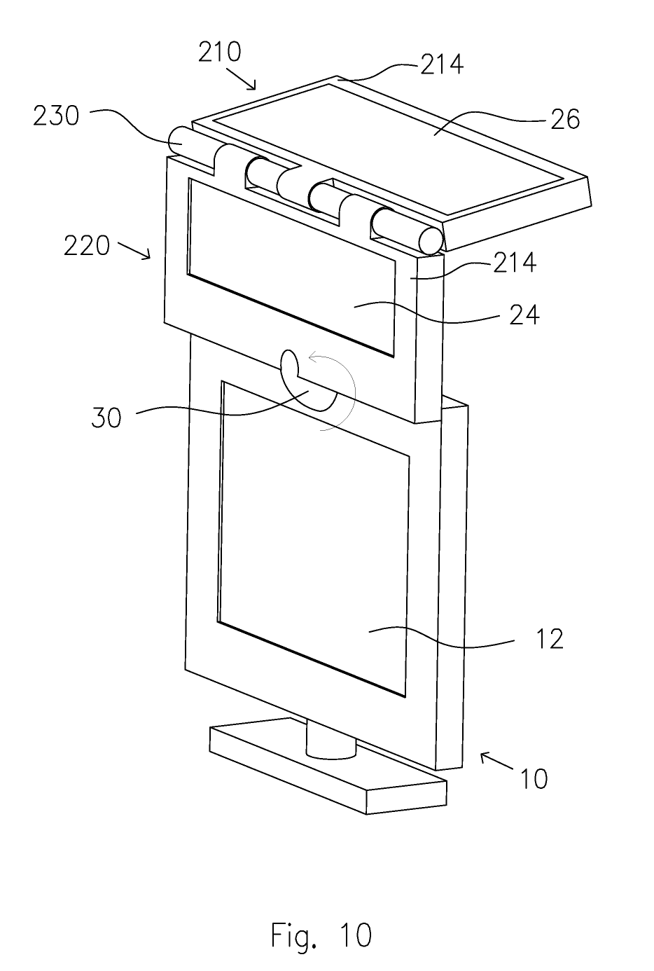

Please refer to FIG. 9, when the protective cover 20 is rotated upwards into the second position P2, the first cover 210 swivel facing upwards and the inner face 212 with the light source 28 facing downwards providing illumination for the user while using the display, wherein the light source 28 may be an LED. Furthermore, the solar panel 26 on the outer face 214 can absorb sunlight and converts the solar energy into electricity for the display or the illumination. When the second cover 220 is parallel with the display body 10, the second screen 22 and the third screen 24 can display images or information for the user or the third party. When the second cover 220 rotates backwards facing upwards or facing sunlight, the solar panel 26 absorbs sunlight then converts the solar energy into electricity and supplies it to the display as shown in FIG. 10.

Multi-swivel dual screen display allows the user to swivel additional screens in all various positions and displaying images or other information on the screens. When the display is not in use, the protective cover can be swivel in front of the screen protecting the screen from dust and scratches.

Further scope of applicability of the invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

1. A multi-swivel dual screen display, comprising:
a display body having a screen and a concave slot, wherein the concave slot is disposed on a top of the screen;
a protective cover includes a second screen; and
a ball joint having a first end and a second end, wherein the first end is pivotally coupled to the protective cover, and the second end connected to the concave slot of the display body thus enable the protective cover to be multi-swivel in all positions.

2. A multi-swivel dual screen display of claim 1, wherein the ball joint and the concave slot is a tight fit joint.

3. A multi-swivel dual screen display of claim 1, wherein the screen is a touch panel screen.

4. A multi-swivel dual screen display of claim 1, wherein the second screen is a touch panel screen.

5. A multi-swivel dual screen display of claim 1, wherein the protective cover comprises a first cover, a second cover and a hinge, wherein the hinge is pivotally connects the first cover and the second cover.

6. A multi-swivel dual screen display of claim 5, wherein the second cover is pivotally coupled to the ball joint.

7. A multi-swivel dual screen display of claim 1, wherein the protective cover has same size as the display body.

8. A multi-swivel dual screen display of claim 1, wherein a solar panel is disposed on the protective cover.

9. A multi-swivel dual screen display of claim 5, wherein a solar panel is disposed on the first cover.

10. A multi-swivel dual screen display of claim 5, wherein the first cover having a light source.

11. A multi-swivel dual screen display of claim 5, wherein the second cover having a third screen.
